(19) United States
(12) Patent Application Publication
(10) Pub. No.: US 2025/0208586 A1
(43) Pub. Date: Jun. 26, 2025

(54) DEVICE FOR TRANSMITTING A WATCH MESSAGE

(71) Applicant: ETA SA Manufacture Horlogère Suisse, Grenchen (CH)

(72) Inventors: Dominique DUBUGNON, Saint-Prex (CH); Pierpasquale TORTORA, Neuchâtel (CH); Sylvain HUOT-MARCHAND, Eschert (CH); Raphaël COURVOISIER, Corcelles (CH)

(73) Assignee: ETA SA Manufacture Horlogère Suisse, Grenchen (CH)

(21) Appl. No.: 18/955,179

(22) Filed: Nov. 21, 2024

(30) Foreign Application Priority Data
Dec. 22, 2023 (EP) 23220079.0

(51) Int. Cl. G04G 21/02; G04G 19/00; H02J 7/35

(52) U.S. Cl. CPC G04G 21/02; G04G 19/00; H02J 7/35; H02J 2300/24

(57) ABSTRACT

A dial (2a, 2b) of a watch (1) including a standalone device for transmitting a message (3) to an electronic device, such a dial (2a, 2b) comprises a visible face (20a) and a hidden face (20b), the dial (2a, 2b) being formed by a stack (9a, 9b) of thin layers (10, 11, 12, 13, 14) of material extending between these two faces (20a, 20b), each of the layers (10, 11, 12, 13, 14) including one or more of the functional elements comprised in the device (3): at least one message transmission activation sensor (23); at least one light source (4); a standalone electric power supply unit (21); and a control unit (7) for managing the operation of the at least one light source (4) and of the at least one activation sensor (23).

### CROSS REFERENCE TO RELATED APPLICATIONS

This application is claiming priority based on European Patent Application No. 23220079.0 filed on Dec. 22, 2023.

### TECHNICAL FIELD OF THE INVENTION

The present invention relates to a watch comprising a dial including a device for transmitting a message, the device being completely standalone.

### TECHNOLOGICAL BACKGROUND

In the prior art, electromechanical watches with hands are known, wherein the hour and minute hands displaying the current time are driven by the trains of a horological movement mechanism. In this context, it might happen that, because of shocks given to the watch, the presence of electromagnetic fields or other external disturbances, the operation of the mechanism might be disturbed. In order to limit and even avoid any damage to this mechanism, it is often necessary to identify at an early stage the disturbance(s) that may be the cause thereof, as well as the malfunctions caused in the mechanism by these disturbances.

In this context, it should be understood that there is a need to find a solution that does not have the drawbacks of the prior art.

### SUMMARY OF THE INVENTION

The invention aims to overcome these drawbacks by providing a watch with a dial including a message transmission device which is standalone and has an effectiveness that remains constant over time.

One aspect of the invention relates to a watch dial comprising a standalone device for transmitting a message to an electronic device, such a dial comprises a visible face and a hidden face which are substantially flat, opposite each other and connected to each other by a peripheral wall, said dial being formed by a stack of thin layers of material extending between these two faces, each of said layers comprising one or more of the functional elements comprised in said device:
at least one message transmission activation sensor;
at least one light source;
a standalone electric power supply unit; and
   a control unit (7) for managing the operation of said at least one light source (4) and said at least one activation sensor.

In other embodiments:
said at least one activation sensor configured to generate at least one electrical signal towards the control unit triggering the transmission of the message to the electronic device;
said at least one light source is a punctual light source;
said control unit is configured to control said at least one light source by controlling blinking thereof according to the information included in said message;
the stack of thin layers of material comprises a first layer provided with the visible face of the dial and comprising said at least one activation sensor and said at least one light source;
said at least one activation sensor is arranged in a cavity formed in the hidden face of this dial;
said first layer is configured to be crossed in whole or in part by light radiation, in particular solar radiation;
said first layer is wholly or partly transparent or translucent;
the stack of thin layers of material includes a second layer comprising a photovoltaic module making up the standalone electric power supply unit;
the second layer comprises a substrate on which the photovoltaic module is printed;
said photovoltaic module is arranged on an active area of said second layer, said area being configured to receive light radiations originating from the first layer of the stack of thin layers of material;
the stack includes a third layer comprising an electrical energy accumulator making up the standalone electric power supply unit;
the third layer comprises a substrate on which the electrical energy accumulator is printed;
the stack includes a fourth layer forming a hidden face of the dial comprising the control unit;
the stack includes a third layer comprising a hidden face of the dial including the control unit and an electrical energy accumulator making up the standalone electric power supply unit;
the first layer is rigid compared to the other layers in the stack of thin layers of material, which are soft.

Another aspect of the invention relates to a watch comprising such a dial.

Advantageously, the watch comprises a mechanical, electronic or electromechanical horological movement.

### BRIEF DESCRIPTION OF THE FIGURES

The aims, advantages and features of the watch according to the invention will become clearer in the following description on the basis of at least one non-limiting embodiment illustrated by the drawings wherein:

FIG. 1 shows a perspective view of a watch comprising a watch dial provided with a device for transmitting a message which is standalone, according to some embodiments of the invention;

FIG. 2 shows an exploded view of a first variant of the dial formed by a stack of four superimposed layers, each of said layers including one or more constituent element(s) of the transmission device, according to a first embodiment of the invention;

FIG. 3 shows a schematic view of this first variant of the dial provided with the transmission device, according to the first embodiment of the invention;

FIG. 4 shows an exploded view of a second variant of the dial formed by a stack of three superimposed layers, each of said layers including one or more constituent element(s) of the transmission device, according to a second embodiment of the invention; and

FIG. 5 shows a schematic view of this second variant of the dial provided with the transmission device, according to the second embodiment of the invention.

### DETAILED DESCRIPTION OF THE INVENTION

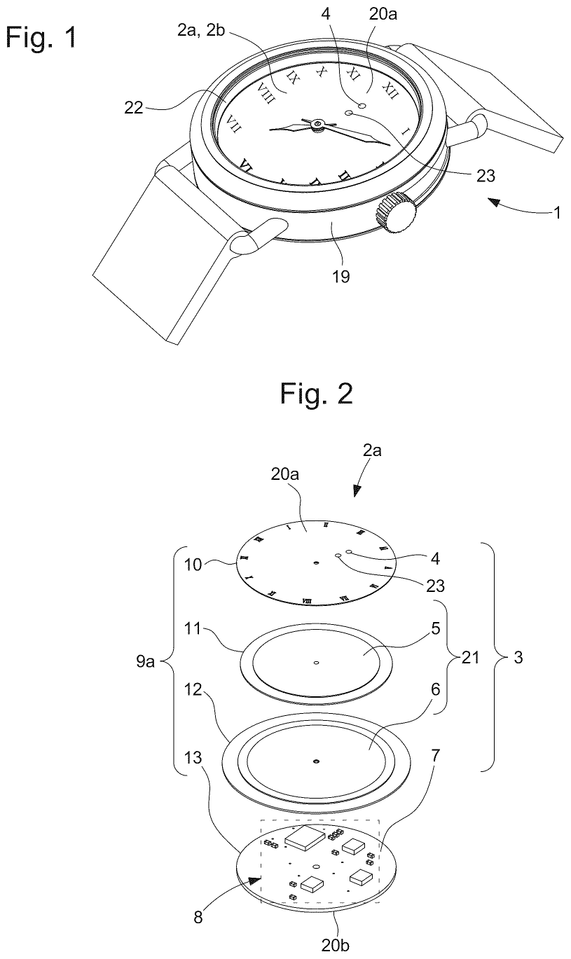

FIG. 1 shows a schematic illustration of a watch 1 comprising a case 19 provided with a middle to which a back and a crystal 22 are fastened, a set of components forming a horological movement, and a dial 2a, 2b arranged between the horological movement and the crystal 22.

In a manner known to a person skilled in the art, the horological movement drives a set of hands comprising an hour hand, a minute hand and possibly a second hand. To this end, the dial 2a, 2b includes a through hole receiving the axis of the hands. This dial 2a, 2b also comprises two faces 20a, 20b including:
A so-called visible face 20a visible from the outside of the watch 1, also known as the “visible portion” or “visible upper portion” of this dial 2a, 2b; and
a so-called hidden face 20b arranged opposite the horological movement in an enclosure of the case 19 of the watch 1, this face 20b being otherwise so-called the “hidden portion” or “hidden lower portion” of this dial 2a, 2b.

Such a visible face 20a may comprise, in a non-limiting and non-exhaustive manner, at least one graphic representation such as:
a marker (or display) element like, for example, a digit, an index, a line or a dot contributing, with or without the hands, to the display of a horological information/measurement or a physical information/measurement measured by a sensor or the like comprised in the movement;
an inscription, a pattern, a text, a logo, etc.

These visible 20a and hidden 20b faces are substantially flat and/or parallel and/or opposite each other. In other variants, note that the dial 2a, 2b may comprise a domed visible face and a hidden face which may be domed or flat. These faces 20a, 20b are also joined together by a peripheral wall of this dial 2a, 2b.

Moreover, it should be noted that in the embodiments illustrated in FIGS. 1 to 5, the dial 2a, 2b preferably has a circular shape. It should be understood that the invention may also be implemented for dials 2a, 2b having other shapes like, for example, a triangular shape or a quadrilateral-like shape.

In the embodiments of the invention, the horological movement is a mechanical movement. Alternatively, this movement may be an electromechanical or electronic movement. Next, we will refer to a mechanical watch when its movement is mechanical, to an electromechanical watch when it includes an electromechanical movement and to an electronic watch when it includes an electronic movement.

With reference to FIGS. 2 and 4, such a dial 2a, 2b comprises a message transmission device 3 which is standalone. This transmission device 3 comprises its own electric power supply means, as we shall see later on. Such a message transmission device 3 is said to be standalone in particular with respect to the movement of the watch 1 and in particular with respect to the energy source of this movement, for example when this source is an electric power supply like in an electromechanical or electronic movement. Under these conditions, it should be understood that the energy used by this transmission device 3 is not used to the detriment of the autonomy of the movement.

Such a transmission device 3 enables this watch 1 to transmit a message to an electronic device. This message may comprise information relating to functions implemented by the watch 1, like time functions, or functions implementing monitoring of events relating to the operation of the movement of this watch, like, for example, an event relating to a leak in the case 19 of the watch 1. Other examples of types of information likely to be included in this message may include, but are not limited to:
the count of the number of passages of at least one hand, if the watch 1 is so equipped, allowing for example determining the real operating time of this watch 1, for example between two servicing or maintenance operations;
the number and the nature (weak, strong) of shocks received by the case 19, when the dial 2a, 2b is provided with an accelerometer;
the number and the intensity of exposures of the watch 1 to magnetic fields, when the dial 2a, 2b is provided with a magnetic sensor;
the internal pressure and/or humidity of the case 19, which could indicate a leak in the watch 1, when the dial is provided with a pressure and/or humidity sensor;
the orientation of the watch 1, and the duration of these orientations, when the dial 2a, 2b is equipped with a gyroscope, in order, for example, to improve the adjustment of the watch according to its wearer, or to adapt the frequency of the maintenance services necessary for the proper operation of the watch 1, this may form part of predictive maintenance;
the detection of abnormal operating noises when the dial 2a, 2b is equipped with an acoustic sensor, allowing predicting or signalling a fault or a malfunction.

Hence, it should be understood that, in this context, the transmission device 3 may comprise, in a non-limitative and non-exhaustive manner, the following event sensors:
position sensor for a watch hand;
accelerometer sensor;
pressure sensor;
humidity sensor;
angular position sensor;
gyroscopic and/or inertial sensor in the form of an electronic component and/or of the gyroscopic inertial electromechanical microsystem circuit type;
acoustic sensor.

In this context, such an electronic device is preferably a mobile device. This device, also known as a user terminal, is capable of being carried and transported by a user, and of being functional while being transported. This is the case, for example, of a smartphone or a tablet. This electronic device preferably comprises a microcontroller, an optical sensor such as a photographic sensor, a punctual light source and elements for broadcasting the received message such as a screen and/or a loudspeaker. In this configuration, this electronic device is used to receive, decode and broadcast the message transmitted by the transmission device of the watch 1.

In the case 19 of the watch 1, the dial 2a, 2b may be removably mounted and that being so, regardless of the type of the watch 1. The only condition to be met is that the dial 2a, 2b comprises the transmission device 3, which is therefore standalone with respect to the movement of this watch 1. This dial 2a, 2b is also called a “standalone dial” because it is not connected, in particular electrically, to the movement of the watch 1. This dial 2a, 2b may be considered as a part attached to the watch 1.

This transmission device 3 comprised in this dial 2a, 2b, includes at least one light source 4, also known as a light source, a standalone electric power supply unit 21, at least one message transmission activation sensor 23, and a control unit 7.

In this device 3, said at least one light source 4 is preferably a point source which is implemented to contribute to the transmission of the message. The light produced by said at least one punctual light source 4 therefore illuminates a punctual or quasi-punctual area of the dial 2a, 2b. To do so, the light originating from each light source 4 can, for example, be collimated or focused towards the considered punctual or quasi-punctual area, by any known collimation or focusing means. This “punctual or quasi-punctual area” comprises any area located on/in the visible face 20a of the dial 2a, 2b, and has dimensions such that it is perceived as distinct from neighbouring areas by the human eye.

Each punctual light source 4 may correspond to any electroluminescent element selected from a non-exhaustive and non-limiting list comprising:
a light-emitting capacitor known by the acronym LEC standing for “Light-Emitting Capacitor”;
a light-emitting diode such as LED (acronym for “Light-Emitting Diode”), OLED (acronym for “Organic Light-Emitting Diode”), AMOLED (acronym for “Active-Matrix Organic Light-Emitting Diode”) or QLED (acronym for “Quantum Light-emitting diode”);
any electroluminescent material activated by a local electric field;
any electroluminescent material activated by an electric current;
any combination of these electroluminescent elements.

Alternatively, not shown in the figures, the punctual light source 4 may be a quantum box or quantum dot.

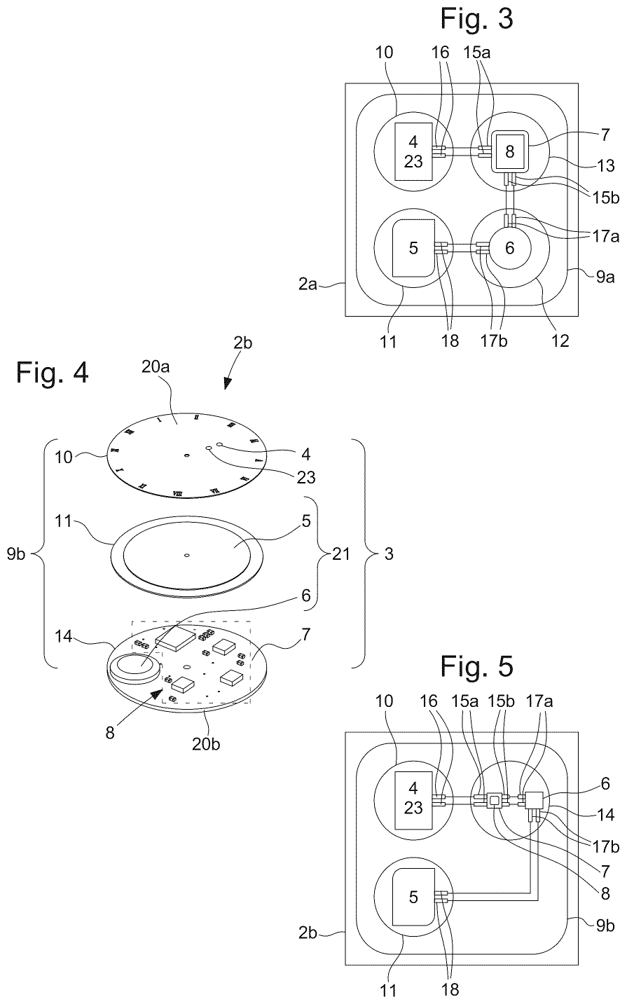

In this transmission device 3, the standalone electric power supply unit 21 includes an electrical energy accumulator 6 and a photovoltaic module 5 comprising at least one photovoltaic cell, also known as a solar cell. This photovoltaic module 5 is connected to the electrical energy accumulator 6 via connection elements referenced 17b and 18 in FIGS. 3 and 5. This photovoltaic module 5 may comprise one or more elementary cell(s) of the heterojunction or multijunction type, connected in parallel or in series. Each photovoltaic cell of this module 5 may be made, in a manner known to a person skilled in the art, from semiconductor materials based on copper, indium, gallium and selenium, based on cadmium telluride, based on monocrystalline gallium arsenide or based on monocrystalline or polycrystalline silicon, or with perovskites. It should be noted that these examples are not limiting and that a person skilled in the art will be able to find the type of photovoltaic cell suitable for the invention.

In this transmission device 3, the control unit 7, also known as microcontroller, includes an electronic circuit 8 comprising hardware resources, in particular at least one processor cooperating with memory elements as well as address, data and control buses. This control unit 7 is connected to said at least one light source 4, to said at least one activation sensor 23 and to the standalone electric power supply unit 21.

Such a control unit 7 comprises in its memory elements a message transmission algorithm. This algorithm is capable of implementing a message transmission by defining a sequence of light pulses for broadcasting a light radiation by said at least one light source 4 and that being so, by means of an optical modulation or coding applied to this radiation. This modulation or coding provides for the control of a blinking of this light source 4 by making it alternate between two states: on or off. In this context, the sequence of light pulses, also known as the “transmission sequence” or “transmission light pulse sequence”, depends on the content of the message, in other words the information contained in this message. Thus, by executing this algorithm, the control unit 7 is able to drive/control the blinking of the punctual light source 4 according to the defined transmission sequence.

In this transmission device 3, the message transmission activation sensor 23, which may in particular also be referred to as the activation sensor 23 of the transmission device 3, may comprise:
at least one optical sensor which is able to receive a sequence of light pulses, also called an “initiation sequence” or “initiation light pulse sequence”, from the punctual light source of the electronic device to trigger activation of the transmission of a message;
at least one acoustic sensor which is able to detect, for example, tapping on a trim element (e.g.: the crystal) of the watch to trigger activation of the transmission of a message;
at least one sensor of the accelerometer type for detecting a vibration, a jolt imparted on the watch to trigger activation of the transmission of a message;
at least one sensor of the gyroscope type for detecting a vibration, a jolt imparted on the watch to trigger activation of the transmission of a message;
at least one sensor of the accelerometer type and at least one sensor of the gyroscope type to detect together a vibration, a jolt imparted on the watch to trigger activation of the transmission of a message.

The activation sensor 23 is configured to generate at least one electrical signal to the control unit 7 to trigger or cause the transmission of said message.

Moreover, it should be noted that the control unit 7 may also comprise in its memory elements an algorithm for managing the electrical energy accumulator 6, in particular the management of recharging thereof by the photovoltaic module 5 and the management of the electrical consumption by said light source 4 and also that of the activation sensor 23.

Thus, as already mentioned, the standalone transmission device 3 is therefore comprised in the dial 2a, 2b. In this configuration, the constituent elements of this transmission device 3, namely the light source 4, the electrical energy accumulator 6, the photovoltaic module 5, the activation sensor 23 and the control unit 7, are comprised in one or more layer(s) 10, 11, 12, 13, 14 forming this dial 2a, 2b.

With reference to FIGS. 2 to 5, this dial 2a, 2b is formed by or consist of a stack 9a, 9b of a plurality of thin/fine layers 10, 11, 12, 13, 14, these layers 10, 11, 12, 13, 14 are joined together by a joining element such as an adhesive substance so as to unify them in order to obtain a stack 9a, 9b of monolithic thin layers thereby forming a one-piece dial 2a, 2b. This joining element may also be a clip or a screw. Such layers 10, 11, 12, 13, 14 are superimposed in the stack 9a, 9b of layers, i.e. they are arranged on top of one another in this dial 2a, 2b according to a defined order. Note that such a stack 9a, 9b of layers may also be called an assembly of layers. In this stack 9a, 9b, the layers are substantially similar, having upper and lower surfaces with substantially the same areas/surfaces, thereby contributing to forming the peripheral wall of the dial 2a, 2b, which has no relief.

It should be noted that these thin or fine layers are layers each having a micrometric thickness. Indeed, each layer may have a thickness comprised between 1 and 100 μm, preferably 2 μm, or preferably 3 μm. As regards to the thickness of the dial 2a, 2b, it may be between 8 and 400 μm, preferably 6 μm or preferably 12 μm or preferably 100 μm or preferably 200 μm or preferably 300 μm.

Thus, such a one-piece dial 2a, 2b has the additional advantage of being able to be removably mounted in the case 19 of the watch 1, in addition to facilitating integration thereof in this case 19.

In a first variant of this stack 9a of layers illustrated in FIG. 3, the latter is made up of four successive thin/fine layers 10, 11, 12, 13 as follows:
a first layer 10 forming/making up the visible face 20a of the dial 2a including said at least one light source 4 and said at least one activation sensor 23 of the transmission device 3;
a second layer 11 including the photovoltaic module 5;
a third layer 12 including an electrical energy accumulator 6, also known as a rechargeable battery; and
a fourth layer 13 forming the hidden face 20b of the dial 2a including the control unit 7.

The first layer 10 of this stack 9a is preferably rigid or semi-rigid in comparison with the second, third and fourth thin/fine layers 11, 12, 13 which are preferably soft or flexible. It should be understood herein that such a first layer 10 contributes to structurally stiffening the stack 9a of thin layers and therefore the dial 2a.

In this stack 9a, each of the first, second, third and fourth layers 10, 11, 12 and 13 comprises an upper surface and a lower surface.

As regards the first layer 10, it is formed by a transparent or translucent or at least partially transparent or at least partially translucent rigid or semi-rigid substrate. Such a substrate is made of a material having a transmittance to solar radiation, in particular ultraviolet radiation, also known as UVT (standing for “Ultra-Violet Transmission”) which is comprised between 65 and 95 percent. This transmittance is preferably 85 percent. Such a material may be transparent or translucent. This material may be, but is not limited to, a polymer, glass or ceramic.

In this context, it should be understood that this substrate is configured so that:
the light produced by said at least one light source could escape to the outside of the dial 2a, 2b and therefore of the watch 1; and
the light originating from the environment of the watch 1 could penetrate the dial 2a, 2b in the direction of the photovoltaic module 5 of the transmission device 3, this light comprising solar radiation when it is of natural origin.

In other words, this transparent or translucent substrate is configured to be crossed by this light which could supply the photovoltaic module 5 so that the latter could convert the solar energy originating from this radiation into electrical energy.

This first layer 10 also comprises at least one light source 4 which is arranged in the body of the substrate. Such an arrangement of the light source 4 in this substrate is configured to ensure illumination of the punctual area of the visible face 20a of the dial 2a.

This lighting may be a direct lighting when the light source 4 is arranged in a cavity defined in the substrate. This cavity may be a blind opening made in the lower surface of this substrate, and whose bottom forms or comprises the punctual area. In this configuration, the light radiation, or light, produced by this light source 4 can escape through this punctual area of this cavity towards the outside of the dial 2a and therefore through the visible face 20a of this dial 2a.

This lighting may also be direct lighting when the light source 4 is arranged in a through opening extending across the thickness of the substrate of the first layer 10, opening out at its two ends respectively in the upper and lower surfaces of this substrate. In this configuration, all or part of the light source 4 may project from the upper surface of this substrate and therefore from the first layer 10 or from the visible face 20a of the dial 2a to form the punctual area.

Such lighting may also be a remote lighting when said at least one light source 4 is coupled to at least one waveguide. This waveguide, also known as a light guide, allows carrying the light from the point where it is injected into the guide up to the punctual area of the substrate defined in the upper surface of this substrate. Such a light guide may be an optical fibre which allows circumventing any obstacles that might be erected in the substrate, for example between the electroluminescent element and the punctual area through which the light will escape. In this variant, the light is therefore carried, via the waveguide, from the electroluminescent element up to the punctual area to be illuminated.

In such a configuration, a first end of the waveguide is coupled to the light source 4 and a second end of this waveguide may be arranged in:
a cavity which could be a blind opening made in the lower surface of the substrate of this first layer 10, the bottom of this cavity making up the punctual area; or
a through opening extending in the thickness of the substrate of the first layer 10 and opening out at its two ends respectively into the upper and lower surfaces of this substrate and therefore of the first layer 10. Thus, this second end may project from the upper surface of the substrate or from the visible face 20a of the dial 2a in order to form the punctual area.

In this first layer 10, the light source 4 and the activation sensor 23 is applied/fastened to the lower or upper surface of the substrate of this first layer 10, in a cavity or on an inner wall of a through opening, by printing or evaporation.

In this first layer 10, the activation sensor 23 is arranged in/on this substrate so as to be able to receive the light radiation from the electronic device modulated according to the initiation sequence. This activation sensor 23 may be arranged over or under the upper surface of this substrate forming the first layer 10. When arranged in the substrate, this activation sensor 23 is positioned in a blind cavity formed in this upper surface. In one variant, it may be arranged in a blind cavity made in the lower surface of this substrate having this upper surface as its bottom. In another variant, this activation sensor 23 may be arranged in a through opening formed in this substrate connecting the upper and lower surfaces together.

Furthermore, it should be noted that the lower surface of this first layer 10 may be self-adhesive in order to contribute to assembly thereof with the second layer 11.

In this stack 9a, the second layer 11 comprises a substrate including the photovoltaic module 5. Such a substrate is preferably flexible or soft. This substrate of the second layer 11 may be a film on which the photovoltaic module 5 is arranged. Finally, this substrate may be made of a material belonging to the polymer family.

In this second layer 11, the photovoltaic module 5 preferably extends over the whole of a so-called active area of the upper surface of this substrate. This active area is a portion of the upper surface of the substrate that is able to receive light originating from the lower surface of the first layer 10 of the dial 2a. This light, which has passed through all or part of the first layer 10, originates from the external environment of the dial 2a, and therefore of the watch 1, in this case mainly from solar radiation when it is of natural origin.

It should be noted that the photovoltaic module 5 is applied to the upper surface of this substrate using inkjet printing or screen-printing processes or using thermal evaporation printing processes. We will refer herein to a second layer 11 comprising a printed photovoltaic module 5. In particular, a photovoltaic module 5 printed on the substrate of the second layer 11.

One could notice that, once the photovoltaic module 5 has been applied to the substrate, a layer of a self-adhesive substance may be deposited over all or part of the upper surface and/or of the lower surface of the substrate. Under these conditions, the second layer 11 may be a self-adhesive layer which contributes to facilitating assembly thereof with the other layers, in particular with the first layer 10 and/or the third layer 12 of this stack 9a.

In the stack 9a, this third layer 12 also comprises a preferably flexible or soft substrate, including the electrical energy accumulator 6 of the standalone transmission device 3. This substrate of the third layer 12 may be a film on which the accumulator 6 is comprised. Such a substrate may be made of a material belonging to the polymer family.

This accumulator 6 may be a lithium battery or a semiconductor battery. Such an accumulator 6 is applied to the upper surface of this substrate using processes known in the state of the art, such as:
printing processes on a soft polymer substrate, for example for a lithium battery; or
three-dimensional printing processes, for example for a semiconductor battery such as a lithium-metal semiconductor battery.

We will refer herein to a third layer 12 comprising a printed electrical energy accumulator 6. In particular, an electrical energy accumulator 6 printed on the substrate of the third layer 12.

Thus, such processes allow obtaining a third layer 12 comprising this accumulator 6 which is flexible and ultra-fine.

Furthermore, one could notice that once the accumulator 6 has been applied to the substrate, a layer of a self-adhesive substance can be deposited over all or part of the upper surface and/or the lower surface of this substrate. Under these conditions, the third layer 12 may be a self-adhesive layer which contributes to facilitating assembly thereof with the other layers, in particular with the second layer 11 and/or the fourth layer 13 of this stack 9a.

Note that this accumulator 6 is used to store the electrical energy produced by the photovoltaic module 5 and to release it on demand to power the transmission device 3, said at least one light source 4 and said at least one activation sensor 23.

In this stack 9a, this fourth and final layer 13 forms the hidden face of the dial 2a. Such a fourth layer 13 is formed by a substrate, preferably flexible or soft, including the control unit 7. Such a substrate of the fourth layer 13 may, for example, be a flexible PCB on which this control unit 7 is arranged, in particular on the upper surface of this PCB and therefore of the substrate. In this context, the construction of the control unit 7 on this upper surface of the substrate may be carried out using three-dimensional printing processes or polymer printing processes.

In the second variant, the stack 9b forming the dial 2b comprises three thin/fine layers 10, 11, 14, joined together. One could notice that this second variant differs from the first variant in that it therefore comprises three layers 10, 11, 14 instead of four layers 10, 11, 12, 13, like in the first variant. In this second variant, the electrical energy accumulator 6 of the transmission device 3 is now comprised in the third and last layer 14 of this stack 9b with the control unit 7.

Such a third and final layer 14 of this stack 9b, forming the hidden face of the dial 2b, consists of a preferably flexible or soft substrate, on which are built, preferably on the upper surface of this substrate, the accumulator 6 and the electronic circuit 8 making up the control unit 7. Such a construction of the accumulator 6 and of the control unit 7 on this upper surface of the substrate may be carried out using three-dimensional printing processes or polymer printing processes. It should be noted that such a substrate may be, for example, a flexible PCB.

In summary, in this second variant, the stack 9b then comprises:
a first layer 10 forming the visible face 20a of the dial 2b including said at least one light source 4 and said at least one activation sensor 23 of the transmission device 3;
a second layer 11 including the photovoltaic module 5; and
the third layer 14 forming the hidden face 20b of the dial 2b including the accumulator 6 and the control unit 7.

Note that in this second variant, the first and second layers 10, 11 are similar to those of the first variant of the stack 9a.

Moreover, with reference to FIGS. 3 and 5, the electronic circuit 8 of the control unit 7 comprises first connection elements 15a which are connected to connection elements 16 of:
said at least one light source 4 for managing the operation of this light source 4, in particular the transmission of the message; and
said at least one activation sensor 23 to contribute to triggering of the transmission of the message.

This electronic circuit 8 also comprises second connection elements 15b connected to first connection elements 17a of the accumulator 6.

In a third variant that is not shown, the stack of thin/fine layers forming the dial comprises two interconnected layers. One could notice that this third variant differs from the second variant in that it therefore comprises two layers instead of three layers 10, 11, 14, like in this second variant. In this third variant, the photovoltaic module 5 of the standalone transmission device 3 is now comprised in the first layer and in particular on the lower surface of the substrate forming this first layer. This photovoltaic module 5 may be applied to this lower surface of the substrate of this first layer using inkjet printing or screen-printing processes or using thermal evaporation printing processes. It should therefore be noted that this first layer is then similar to the first layers 11 of the first and second variants, except that in this third variant, the first layer additionally comprises the photovoltaic module.

Moreover, in the third variant, and similarly to the second variant, the electrical energy accumulator 6 of the standalone transmission device 3 is comprised in the second and last layer of this stack with the control unit 7. Such a second layer, forming the hidden face of the dial, consists of a preferably flexible or soft substrate, on which are built, preferably on the upper surface of this substrate, the accumulator 6 and the electronic circuit 8 making up the control unit 7. This construction of the battery 6 and of the control unit 7 on the upper surface of the substrate may be carried out using three-dimensional printing processes or polymer printing processes. It should be noted that such a substrate may be a flexible PCB, for example.

In summary, in this third variant, the stack of layers then comprises:
a first layer forming the visible face 20a of the dial including said at least one light source 4 and the photovoltaic module 5, and said at least one activation sensor 23 of the transmission device 3; and
a second layer forming the hidden face 20b of the dial including the accumulator 6 and the control unit 7.

Thus, in an example of message transmission, the electronic device and in particular its punctual light source is arranged opposite the optical sensor forming the activation sensor 23 of the transmission device 3 of the dial 2a, 2b. This punctual light source then emits a light radiation which blinks according to the sequence of initiation light pulses defined to trigger the transmission of said message by the dial 2a, 2b towards/from this electronic device. More specifically, on receiving this initiation sequence, the control unit 7 generates a sequence of transmission light pulses relating to the message to be sent to this device. Next, the control unit 7 triggers the emission of a light beam by said at least one light source 4 of the device 3, by controlling/driving blinking thereof according to this transmission sequence. Once the sequence of light pulses has been received by an optical sensor in the electronic device, it is decoded by the microcontroller of the device to reconstitute the transmitted message, which could then be broadcast.

Furthermore, it should be noted that the aforementioned event sensors of the transmission device 3 are preferably arranged in the first layer 10 and/or the last layer 13, 14 of the stack 9a, 9b of layers and are connected to the control unit 7 of this device 3.

It goes without saying that the present invention is not limited to the embodiments just described and that various simple modifications and variants may be considered by a person skilled in the art without departing from the scope of the invention as defined by the appended claims.

1. A dial for a watch comprising a standalone device for transmitting a message to an electronic device, such a dial comprises a visible face and a hidden face, said dial being formed by a stack of thin layers of material extending between these two faces, each of said layers comprising one or more of the functional elements comprised in said device:
at least one message transmission activation sensor;
at least one light source;
a standalone electric power supply unit; and
a control unit for managing the operation of said at least one light source and of said at least one activation sensor.

2. The dial according to the claim 1, wherein said at least one activation sensor configured to generate at least one electrical signal towards the control unit triggering the transmission of the message to the electronic device.

3. The dial according to claim 1, wherein said at least one light source is a punctual light source.

4. The dial according to claim 1, wherein said control unit is configured to control said at least one light source by controlling blinking thereof according to the information included in said message.

5. The dial according to claim 1, wherein the stack of thin layers of material comprises a first layer provided with the visible face of the dial and comprising said activation sensor and said at least one light source.

6. The dial according to claim 1, wherein said activation sensor is arranged in a cavity formed in the hidden face of this dial.

7. The dial according to claim 1, wherein said first layer is configured to be crossed in whole or in part by light radiation, in particular solar radiation.

8. The dial according to claim 1, wherein said first layer is wholly or partly transparent or translucent.

9. The dial according to claim 1, wherein the stack of thin layers of material includes a second layer comprising a photovoltaic module making up the standalone electric power supply unit.

10. The dial according to claim 1, wherein the second layer comprises a substrate on which the photovoltaic module is printed.

11. The dial according to claim 1, wherein said first layer is configured to be crossed in whole or in part by light radiation, in particular solar radiation, the photovoltaic module being arranged on an active area of said second layer, said area being configured to receive light radiations originating from the first layer of the stack of thin layers of material.

12. The dial according to claim 1, wherein the stack includes a third layer comprising an electrical energy accumulator making up the standalone electric power supply unit.

13. The dial according to claim 1, wherein the stack includes a third layer comprising an electrical energy accumulator making up the standalone electric power supply unit, the third layer comprising a substrate on which the electrical energy accumulator is printed.

14. The dial according to claim 1, wherein the stack includes a fourth layer forming a hidden face of the dial comprising the control unit.

15. The dial according to claim 1, wherein the stack includes a third layer comprising a hidden face of the dial including the control unit and an electrical energy accumulator making up the standalone electric power supply unit.

16. The dial according to claim 1, wherein the first layer is rigid compared to the other layers comprised in the stack of thin layers of material which are soft.

17. The dial according to claim 1, wherein said visible and hidden faces are flat or domed.

18. A watch comprising the dial according to claim 1.

19. The watch according to claim 18, further comprising a mechanical, electronic or electromechanical horological movement.
